(19) United States
(12) Patent Application Publication
(10) Pub. No.: US 2011/0272023 A1
(43) Pub. Date: Nov. 10, 2011

(54) SOLAR CELL PACKAGING STRUCTURE

(75) Inventors: Yu-Fu Lee, Taoyuan (TW); Yao-Ming Lin, Taoyuan (TW); Yung-Lung Lu, Taoyuan (TW); Chen-Feng Lu, Taoyuan (TW); Shin-Shian Lin, Taoyuan (TW); Sheng-Yen Hsu, Taoyuan (TW)

(73) Assignee: DJ SOLAR CO., LTD., Taoyuan (TW)

(21) Appl. No.: 12/776,368

(22) Filed: May 8, 2010

(51) Int. Cl. H01L 31/00

(52) U.S. Cl. 136/259

(57) ABSTRACT

A lightweight, spill resistant, impact resistant and shatter resistant solar cell packaging structure practical for use in a portable product is disclosed to include a top covering layer and a bottom covering layer respectively molded from a thermoplastic polymer, and a solar cell layer formed of an array of solar cell chips and laminated in between the top covering layer and the bottom covering layer.

### BACKGROUND OF THE INVENTION

1. Field of the Invention

The present invention relates to a solar cell technology and more particularly, to a solar cell packaging structure, which is practical for use in a portable product.

2. Description of the Related Art

Solar cells are intensively used in our daily life for the advantage of environmental friendly and power saving. However, most commercial solar cells are packaged with tempered glass. Because tempered glass cannot be made in a small size, commercial solar cells are commonly made in a big size for a wide area application. Therefore, commercial solar cells are used for water heater and other products that consume much power during operation. For use in a mobile electronic product, mini solar cells are created. FIGS. 1 and 2 illustrate a mini solar cell module according to the prior art. According to this design, the mini solar cell module A comprises a top coating layer A1, a backboard A4, a solar cell layer of an array of solar cell chips A2 bonded between the top coating layer A1 and the backboard A4, and a bottom coating layer A3 bonded between the solar cell layer A2 and the backboard A4. The top coating layer A1 and the bottom coating layer A3 are prepared from epoxy resin. The backboard A4 is prepared from a metal material.

The aforesaid prior art mini solar cell module has drawbacks as follows:

1. The bottom coating layer is prepared from epoxy resin and bonded to the metal backboard. However, because the molecular chain structure of epoxy resin is incomplete when compared to tempered glass, pores tend to occur in the top coating layer and the bottom coating layer. After a long use, epoxy resin may become obscure due to the effect of weather, and may cause the solar cell layer to curve. At this time, hot point stress may occur, lowering the power conversion efficiency of the solar cell layer and shortening the lifespan of the mini solar cell module.

2. Epoxy resin has poor weather resistance. Further, it is difficult to control the thickness of the applied epoxy resin. Uneven thickness of the applied epoxy resin may cause dispersion of light, lowering the power conversion efficiency.

3. The metal backboard is rigid and electrically conductive. When the mini solar cell module is used in a product to be carried on or by a person, the electrically conductive characteristic of the metal backboard has a potential safety risk.

### SUMMARY OF THE INVENTION

The present invention has been accomplished under the circumstances in view. It is the main object of the present invention to provide a solar cell packaging structure, which has lightweight, spill resistant, impact resistant and shatter resistant characteristics, practical for use in a portable product

To achieve this and other objects of the present invention, a solar cell packaging structure comprises a top covering layer and a bottom covering layer respectively molded from a thermoplastic polymer, and a solar cell layer formed of an array of solar cell chips and laminated in between the top covering layer and the bottom covering layer. Further, ethylene-vinyl acetate is applied to bond the top covering layer, the solar cell layer and the bottom covering layer together. Further, a reflector layer may be bonded between the solar cell layer and the bottom covering layer to enhance the power conversion efficiency of the solar cell layer.

### BRIEF DESCRIPTION OF THE DRAWINGS

FIG. 1 is sectional view of a mini solar cell module according to the prior art.

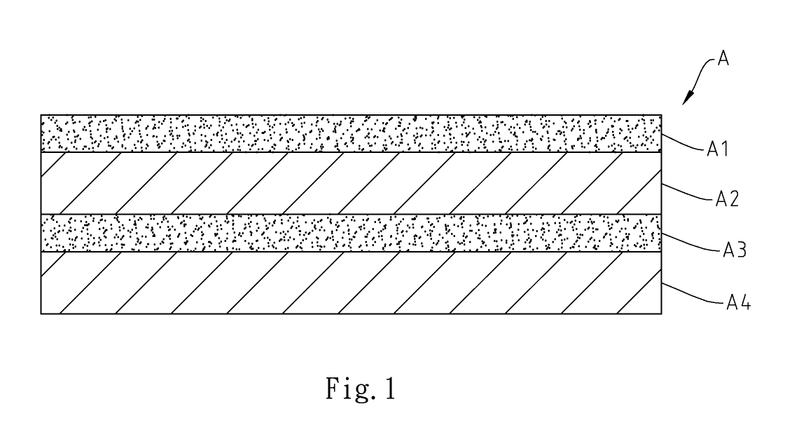

FIG. 2 is an exploded view of the prior art mini solar cell module.

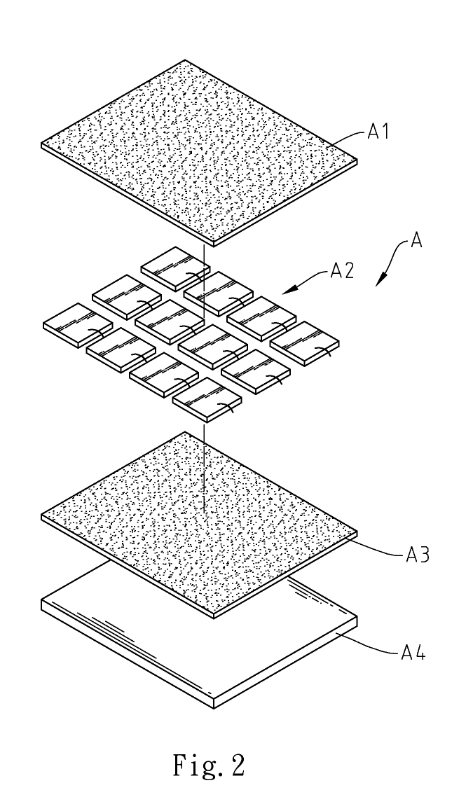

FIG. 3 is a sectional view of a solar cell packaging structure according to the present invention.

FIG. 4 is an exploded view of the solar cell packaging structure according to the present invention.

FIG. 5 is a sectional view of an alternate form of the solar cell packaging structure according to the present invention.

FIG. 6 is an exploded view of the alternate form of solar ell packaging structure according to the present invention.

### DETAILED DESCRIPTION OF THE PREFERRED EMBODIMENT

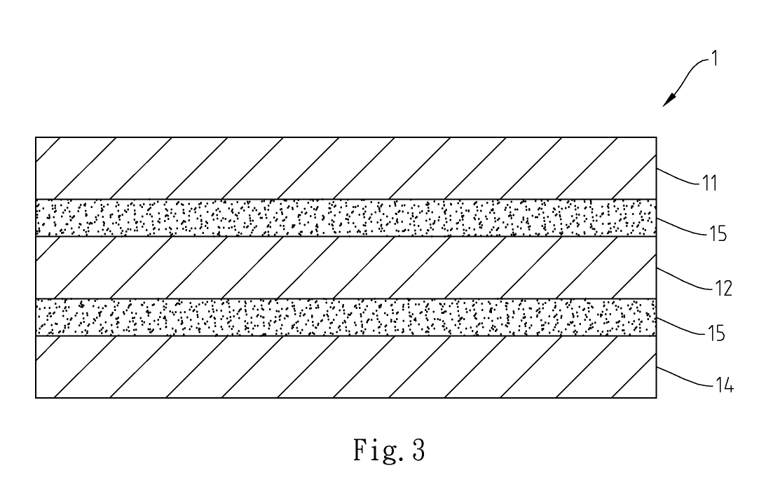

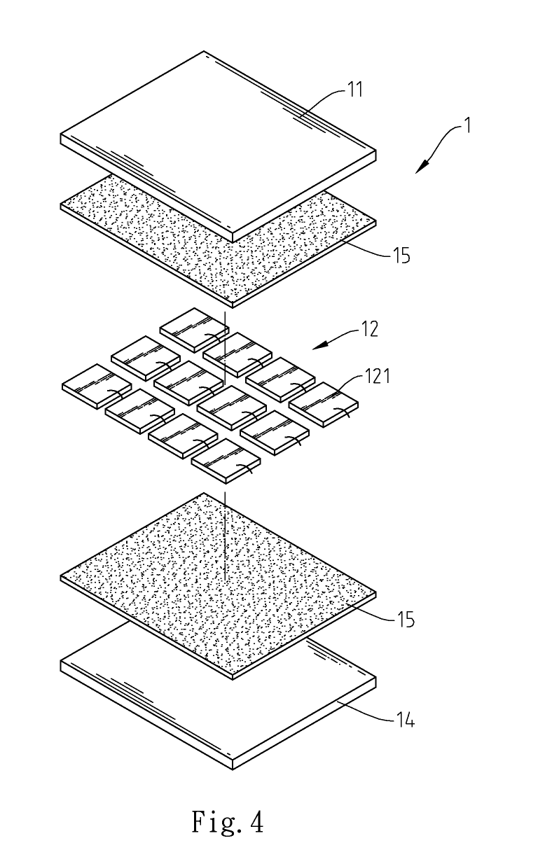

Referring to FIGS. 3 and 4, a solar cell packaging structure 1 in accordance with the present invention is shown comprising a top covering layer 11, a bottom covering layer 14 and solar cell layer 12 arranged in between the top covering layer 11 and the bottom covering layer 14.

The top covering layer 11 and the bottom covering layer 14 are respectively molded from thermoplastic polymers, for example, polycarbonate (PC) for the advantages of low degree of light transmission, excellent bendability, excellent toughness and low fragile temperature.

The solar cell layer 12 comprises a plurality of solar cell chips 121 arranged in an array.

During fabrication, a bonding material, for example, ethylene-vinyl acetate (EVA) is applied to the top and bottom sides of the solar cell layer 12 between the top covering layer 11 and the bottom covering layer 14, and then the top covering layer 11, the solar cell layer 12 and the bottom covering layer 14 are processed through a laminate machine for vacuum packaging, forming a module (panel). Thus, two bonding layers 15 are formed between the top covering layer 11 and the bottom covering layer 14 to bond the top covering layer 11 and the bottom covering layer 14 to the top and bottom sides of the solar cell layer 12.

As the invention uses ethylene-vinyl acetate (EVA) to form the bonding layers 15, the thickness of the bonding layers 15 can be controlled easily and accurately. Further, ethylene-vinyl acetate (EVA) has the advantages of low water absorption, good weather resisting and electrical insulating properties. Thus, the bonding layers 15 effectively protect the solar cell layer 12 without affecting the power conversion efficiency of the solar cell layer 12.

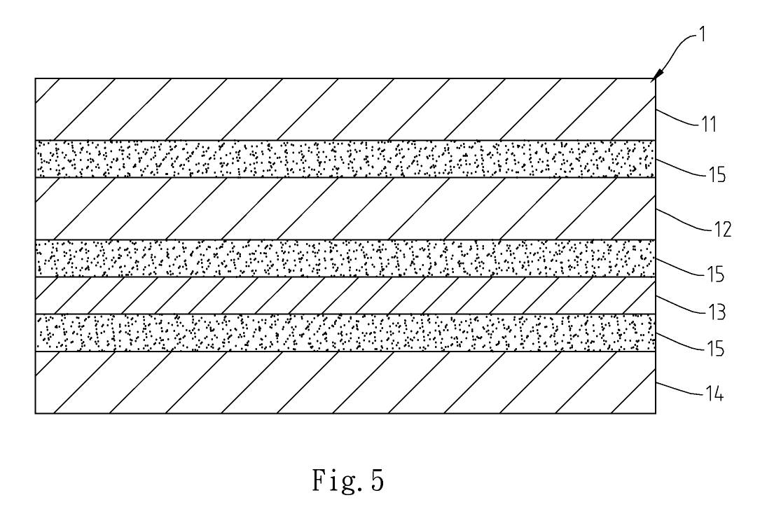

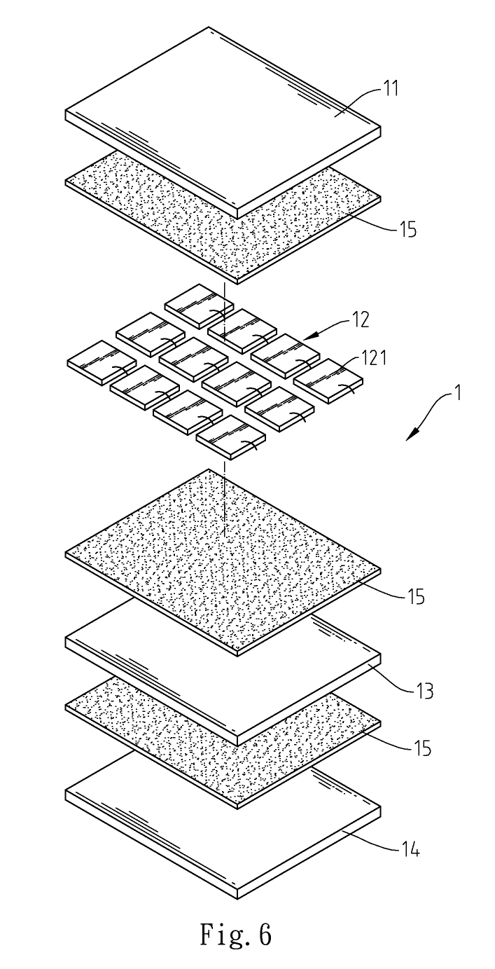

FIGS. 5 and 6 show an alternate form of the present invention. According to this alternate form, the solar cell packaging structure 1 comprises a top covering layer 11, a bottom covering layer 14, solar cell layer 12 arranged in between the top covering layer 11 and the bottom covering layer 14, a reflector layer 13 arranged in between the solar cell layer 12 and the bottom covering layer 14, and bonding layers 15 respectively bonded between the top covering layer 11 and the solar cell layer 12, the solar cell layer 12 and the reflector layer 13, and the reflector layer 13 and the bottom covering layer 14. The bonding layers 15 of this alternate form are also prepared from ethylene-vinyl acetate (EVA). Further, the top covering layer 11, the solar cell layer 12, the reflector layer 13, the bottom covering layer 14 and the bonding layers 15 are laminated through a laminate machine. During application, the incident light that passes through the top covering layer 11 and the gap in between each two adjacent solar cell chips 121 of the solar cell layer 12 is reflected onto the solar cell layer 12 by the reflector layer 13, enhancing the power conversion efficiency of the solar cell layer 12.

Further, the reflector layer 13 can be molded from thermoplastic polymers, for example, polyethylene terephthalate (PET).

In conclusion, the invention provides a solar cell packaging structure that has the advantages of features as below:

1. Because the top covering layer 11 and bottom covering layer 14 of the solar cell packaging structure 1 are prepared from thermoplastic polymers, the solar cell packaging structure 1 is spill resistant, impact resistant and shatter resistant, practical for use in a portable product, such as backpack, cell phone or clothing.

2. Using thermoplastic polymers for making the top covering layer 11 and the bottom covering layer 14 facilitating the fabrication of the solar cell packaging structure 1 in any size to fit small mounting space and special mounting angle. Because the top covering layer 11 and the bottom covering layer 14 are made of the same material, they have same thermal shrinkage, avoiding curving or deformation.

Although particular embodiment of the invention have been described in detail for purposes of illustration, various modifications and enhancements may be made without departing from the spirit and scope of the invention. Accordingly, the invention is not to be limited except as by the appended claims.

What the invention claimed is:

1. A solar cell packaging structure, comprising a top covering layer and a bottom covering layer respectively molded from a thermoplastic polymer, and a solar cell layer laminated in between said top covering layer and said bottom covering layer, said solar cell layer comprising a plurality of solar cell chips arranged in an array.

2. The solar cell packaging structure as claimed in claim 1, wherein the thermoplastic polymer used for making said top covering layer and said bottom covering layer is polycarbonate.

3. The solar cell packaging structure as claimed in claim 1, said solar cell layer has top and bottom sides thereof respectively bonded to said top covering layer and said bottom covering layer by a respective bonding layer prepared from ethylene-vinyl acetate.

4. The solar cell packaging structure as claimed in claim 1, further comprising a reflector layer bonded between said solar cell layer and said bottom covering layer.

5. The solar cell packaging structure as claimed in claim 4, wherein said reflector layer is molded from polyethylene terephthalate.

6. The solar cell packaging structure as claimed in claim 4, wherein said reflector layer has top and bottom sides thereof respectively bonded to said solar cell layer and said bottom covering layer by a respective bonding layer prepared from ethylene-vinyl acetate.
